(19) United States
(12) Patent Application Publication
(10) Pub. No.: US 2026/0123515 A1
(43) Pub. Date: Apr. 30, 2026

(54) METHOD FOR FORMING AN ELECTRONIC DEVICE WITH REDUCED WARPAGES

(71) Applicant: JCET STATS ChipPAC Korea Limited, Incheon (KR)

(72) Inventors: YeoJun YUN, Incheon (KR); SeungHyun LEE, Incheon (KR); HeeSoo LEE, Incheon (KR)

(21) Appl. No.: 19/372,298

(22) Filed: Oct. 29, 2025

(30) Foreign Application Priority Data
Oct. 29, 2024 (CN) 202411521986.7

(51) Int. Cl. H01L 21/56

(52) U.S. Cl. CPC H10W 74/016; H10W 74/014

(57) ABSTRACT

A method for forming an electronic device is provided. The method comprises: disposing a substrate with at least one electronic component mounted thereon within a molding cavity of a molding chase; disposing a molding material within the molding chase; melting the molding material through microwave radiation, and applying a pressure to the molding material to fill the molding cavity with the melted molding material and encapsulate the substrate and the at least one electronic component with the melted molding material; and curing the molding material through microwave radiation to solidify it into a mold cap.

### TECHNICAL FIELD

The present application generally relates to semiconductor technology, and more particularly, to a method for forming an electronic device with reduced warpages.

### BACKGROUND OF THE INVENTION

The semiconductor industry is constantly faced with complex integration challenges as consumers want their electronics to be smaller, faster and higher performance with more and more functionalities packed into a single device. Typically, a semiconductor package may be formed by first mounting electronic components onto a substrate via solder bumps, and then forming a mold cap on the substrate to encapsulate the electronic components. The formation of the mold cap may include a melting process that melts a molding material, and a curing process that solidifies the melted molding material into the mold cap. Both of the melting process and the curing process can be conducted by applying a heating process to the entire device. However, these processes may induce irreversible warpage issues of the substrate and the mold cap due to mismatch in the coefficient of thermal expansion (CTE) between different materials within the device, which may adversely affect device performance and following fabrication processes.

Therefore, a need exists for a method for forming an electronic device with reduced warpages.

### SUMMARY OF THE INVENTION

An objective of the present application is to provide a method for forming an electronic device with reduced warpages.

According to an aspect of the present application, a method for forming an electronic device is provided. The method comprises: disposing a substrate with at least one electronic component mounted thereon within a molding cavity of a molding chase; disposing a molding material within the molding chase; melting the molding material through microwave radiation, and applying a pressure to the molding material to fill the molding cavity with the melted molding material and encapsulate the substrate and the at least one electronic component with the melted molding material; and curing the molding material through microwave radiation to solidify it into a mold cap.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1F illustrate various steps of a method for forming an electronic device according to a first embodiment of the present application.

FIGS. 2A to 2E illustrate various steps of a molding process of a method for forming an electronic device according to a second embodiment of the present application.

FIG. 3 illustrates various steps of a method for forming an electronic device according to a third embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, a semiconductor package may be formed by first mounting electronic components onto a substrate via solder bumps and then forming a mold cap on the substrate to encapsulate the electronic components. Generally, formation of the mold cap may include following steps. Firstly, a molding material may be disposed within a molding chase. Next, a heating process may be implemented to preheat the molding chase and the molding material. A pressure may also be applied to the molding material when it is heated to a high temperature such that the molding material can be melted under the pressure and the high temperature. Then the melted molding material may fill the molding cavity and encapsulate the substrate and the electronic components thereon. Next, the molding material is cured by a heating process and thus solidified into a mold cap. During the processes of melting and curing the molding material, the molding material may be heated by a convection oven which transfers heat to the entire device. The mold cap and the substrate may deform due to mismatch in the coefficient of thermal expansion (CTE) between the substrate and the mold cap, which originates from a material difference between the substrate and the mold cap. Therefore, after the formation of the mold cap, both of the mold cap and the substrate may have warpage issues, which may adversely affect device performance and following fabrication processes.

To address this issue, a method for forming an electronic device is provided. The method includes melting the molding material through microwave radiation with a pressure applied to the molding material to encapsulate the substrate and the at least one electronic component. Additionally, microwave radiation is also applied to cure the molding material and solidify it into a mold cap. The microwave radiation heating process may provide uniform and selective heating to the molding material, which reduces warpage issues of the formed mold cap and the substrate. This improves device performance and facilitates following fabrication processes.

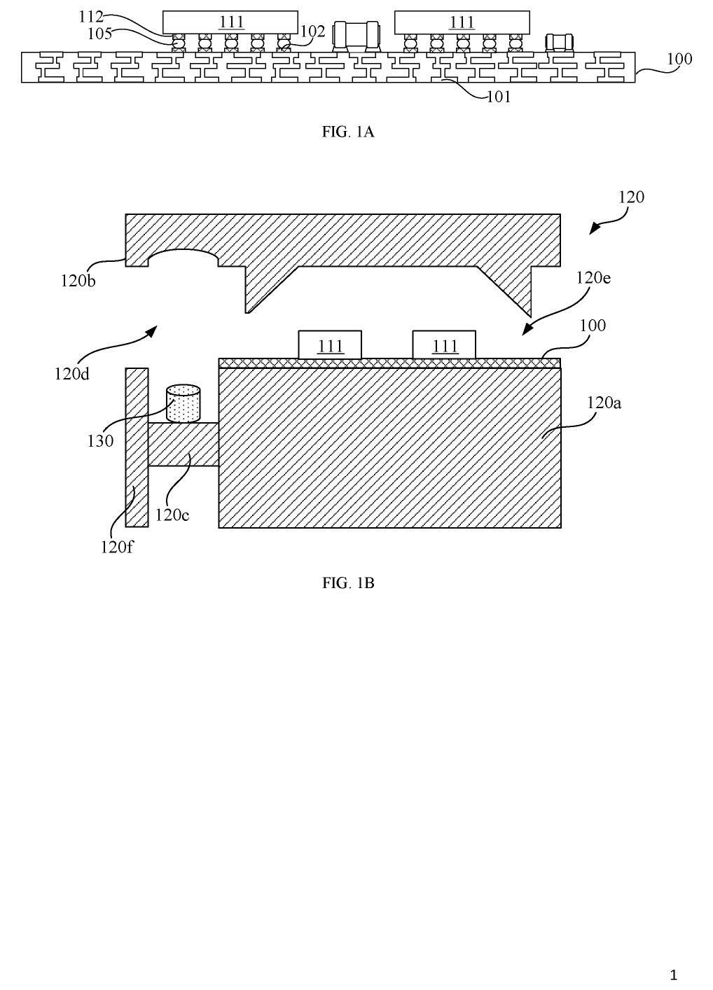

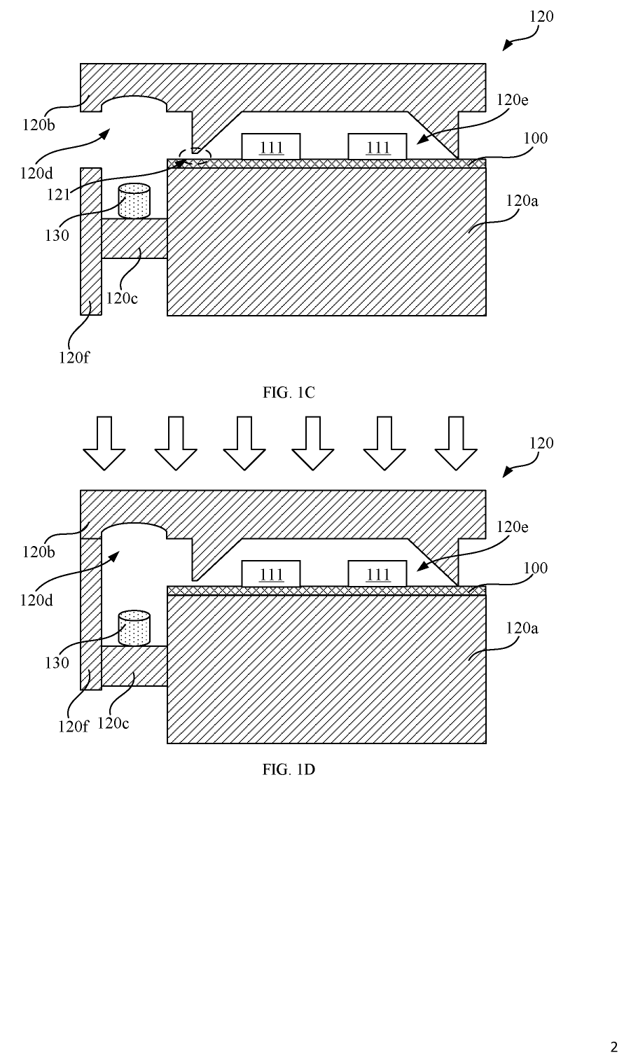

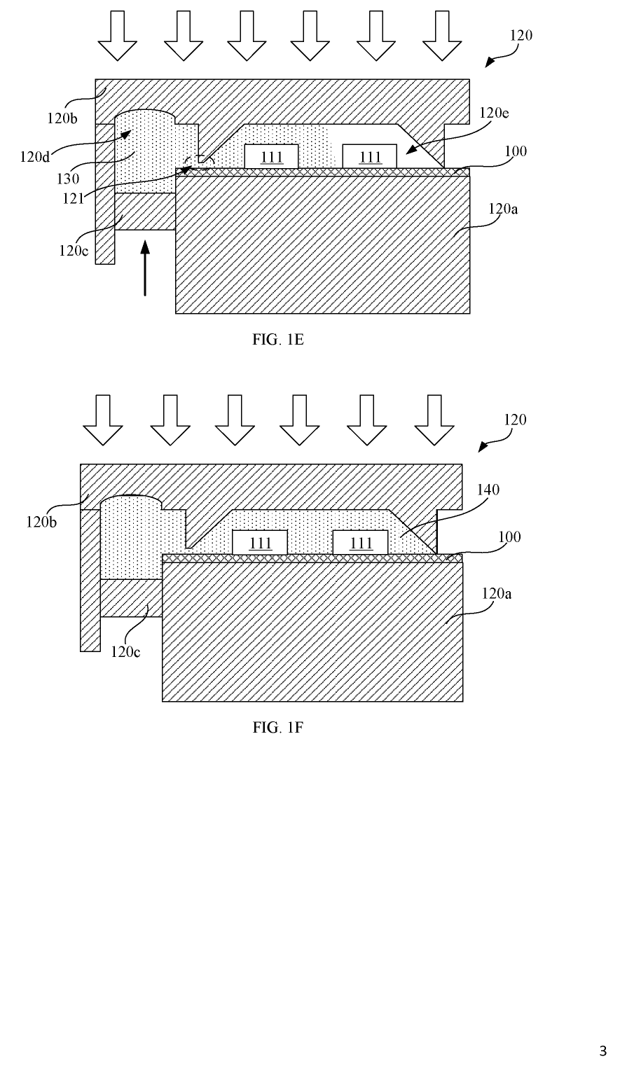

FIGS. 1A to 1F illustrate various steps of a method for forming an electronic device according to a first embodiment of the present application.

As shown in FIG. 1A, a substrate 100 is provided with embedded interconnect wires 101. The substrate 100 includes a front surface, which may serve as a platform where electronic component(s) 111 can be mounted, and a back surface opposite to the front surface. In some embodiments, the substrate 100 may be made of silicon or other semiconductor materials, or may include a printed circuit board (PCB), a carrier substrate, a ceramic substrate, a laminate interposer, a strip interposer, a leadframe, or other suitable substrates. In some embodiments, the substrate 100 includes at least a non-polar material, such as silicon, which is the main part of the material of the substrate 100. It should be noted that the substrate 100 may also contain a minor amount of polar materials. For example, in this embodiment, the substrate 100 may contain more than 99 wt.% of non-polar material(s) and less than 1 wt.% of polar materials, which may be helpful to improve structural and electrical performances of the substrate 100. In some other embodiments, the substrate 100 may contain less than 2 wt.%, 5 wt.% or 10 wt.% of polar materials. The interconnect wires 101 may be formed between and through the substrate 100. Thus, electronic component(s) 111 and other structures on either one surface or both surfaces of the substrate 100 may be electrically coupled with each other to form an integrated electronic system, which will be elaborated below in more details. In some embodiments, a first set of conductive pads 102 can be formed on the front surface of the substrate 100 for the mounting of the electronic component(s) 111. It also can be appreciated that the first set of conductive pads 102 may be exposed portions of interconnect wires 101 formed within the substrate 100.

Next, a solder paste is dispensed or attached on each of the first set of conductive pads 102 for the mounting of the electronic component (s) 111. To be more specific, each of the at least one electronic component 111 may include a second set of conductive pads 112 on its back surface. Each of the second set of conductive pads 112 is aligned with one of the first set of conductive pads 102 with the solder paste disposed therebetween. The at least one electronic component 111 may then be disposed on the front surface of the substrate 100 with the solder paste disposed between the first and second sets of conductive pads 102, 112. In some embodiments, the electronic component 111 may include various types of electronic modules, such as semiconductor chips, resistors, capacitors or other integrated circuit chips. For example, the electronic component 111 may include a semiconductor die. Furthermore, as shown in FIG. 1A, more than one electronic component 111 is mounted on the substrate 100, and the electronic components 111 may have various sizes and be arranged in different layouts. In some embodiments, the at least one electronic component 111 includes at least one non-polar material. It can be appreciated that, similar to the substrate 100 which is illustrated in FIG. 1A, the electronic component 111 may contain a minor amount of polar materials, such as encapsulants or adhesives within the electronic component 111. For example, the electronic component 111 may contain more than 99 wt.%, 98 wt.%, 95 wt.% or 90 wt.% of non-polar material(s), and accordingly less than 1wt.%, 2 wt.%, 5 wt.% or 10 wt.%. of polar materials. In some embodiments, a flux material may further be applied within the solder paste or dispensed to the first set of the conductive pads 102 to facilitate a subsequent reflowing process.

Next, a heating process may be applied to the substrate 100 to heat the solder paste, such that the solder paste can be heated and reflowed to form solder bumps 105 between the first set of conductive pads 102 and the second set of conductive pads 112. The solder bumps 105 so formed can establish an electrical connection between the at least one electronic component 111 and the substrate 100.

Next, a molding process is implemented within a molding chase to form a mold cap that encapsulates the substrate 100 and the at least one electronic component 111. To be more specific, the molding process refers to a transfer molding process, as elaborated below.

As shown in FIG. 1B, a molding chase 120 is provided. In some embodiments, the molding chase 120 may be formed of stainless steel, ceramics, copper, aluminum, or other types of materials. The molding chase 120 includes a base platform 120a and a top cover 120b having a cavity. In this embodiment, the substrate 100 with the at least one electronic component 111 is disposed onto a front surface of the base platform 120a. In some embodiments, the base platform 120a may have air vents which are fluidly coupled to a vacuum source, so as to apply a vacuum pressure to the substrate 100 when it is placed on the base platform 120a. The attraction force applied onto the substrate 100 which is generated by the vacuum pressure may reduce warpage of the substrate 100 during the subsequent molding process. It should be noted that the substrate 100 with the at least one electronic component 111 shown in FIG. 1A may be illustrated with simplified structures in FIG. 1B for clarity. As shown in FIG. 1B, the top cover 120b is disposed above the base platform 120a with the cavity of the top cover 120b aligned with the base platform 120a. The base platform 120a and the top cover 120b may together define a molding cavity 120e when the top cover 120b is attached onto the base platform 120a, and the substrate 100 with the at least one electronic component 111 is accommodated within the molding cavity 120e during the molding process. In some embodiments, a sidewall of the molding cavity 120e of the top cover 120b is slanted with respect to the front surface of the base platform 120a to facilitate the release (or disengagement) of the molding chase 120 from a subsequent formed electronic device. In some other embodiments, the molding cavity may have a cuboid shape, or any other suitable shapes as desired. It can be understood that the configuration of the molding cavity can be designed to accommodate or fit over any underlying structure of the substrate 100 and the electronic component(s) 111 that require encapsulation.

Still referring to FIG. 1B, the molding chase 120 may further include a loading chamber 120d arranged adjacent to the molding cavity 120e and being fluidly connected to the molding cavity 120e when the top cover 120b is attached onto the base platform 120a. To be more specific, a piston 120c may be arranged adjacent to the base platform 120a and be longitudinally movable relative to the base platform 120a. A piston cover 120f may be movably connected to the piston 120c which is used to mechanically support the piston 120c. Furthermore, a portion of the top cover 120b may be aligned with the piston 120c, such that the top cover 120b, the piston 120c, the piston cover 120f and the base platform 120a together define the loading chamber 120d when the top cover 120b is attached onto the base platform 120a. During the subsequent molding process, the piston 120c may be moved relative to the base platform 120a such that a volume of the loading chamber 120d may be reduced.

Next, a molding material 130 is disposed within the loading chamber 120d, more particularly, on a front surface of the piston 120c. The molding material 130 may include a polar material, such as epoxy molding compound including an epoxy-based resin, or other polymer composite materials, and a curing agent. Additionally, the molding material 130 may be in the form of pellets, which can be easily weighed or measured to a required quantity. The molding material pellets 130 can serve as ingredients for forming a mold cap encapsulating the substrate 100 and the at least one electronic component 111. In this embodiment, the top cover 120b is disposed above the base platform 120a and the piston 120c with a channel therebetween to facilitate the loading of the molding material 130.

Next, as shown in FIG. 1C, after the loading of the molding material 130 within the loading chamber 120d, the top cover 120b is moved towards the base platform 120a and the piston 120c to attach the top cover 120b onto the base platform 120a. In some embodiments, the top cover 120b may be mechanically coupled to a driver which automatically controls the top cover 120b to move upward or downward, or move horizontally with respect to the base platform 120a. In some other embodiments, the top cover 120b may be controlled manually, for example, by at least one handwheel or other similar drive mechanism. In this way, the molding cavity 120e may be closed by the top cover 120b and the base platform 120a with a certain shape. It should be noted that a tiny gap may be generated between the loading chamber 120d and the molding cavity 120e to define a fluid port 121, through which the loading chamber 120d can be fluidly connected with the molding cavity 120e.

Next, as shown in FIG. 1D, the piston cover 120f may be moved towards the top cover 120b to close the loading chamber 120d. Next, a microwave source is placed above a top surface of the molding chase 120. Then microwave radiation is applied from the microwave source and penetrates through the molding chase 120 to reach the molding material 130. Since the molding material 130 includes a polar material, dipoles within polar molecules of the molding material 130 are sensitive to an electrical field of the microwave and may rotate to align themselves with a direction of the electrical field. The electrical field of the microwave is periodically changing, which may prompt the dipoles to rotate frequently. As a result, the dipoles may collide with each other when they attempt to follow the electrical field, which generates heat in the molding material 130. In this way, the molding material 130 may be heated rapidly and sufficiently to a temperature between 150 °C and 190 °C, or preferably, to a temperature between 165 °C and 175 °C with a microwave radiation duration between 30 seconds and 2 minutes, which facilitates its melting process. Since the molecules in non-polar materials are not sensitive to electrical fields of the microwaves, the substrate 100 and electronic component 111 may not be heated or may barely be heated by the microwave radiation when they are exposed to the microwaves together with the molding material 130. In addition, the interconnect wires 101 which are embedded within the substrate 100 and metal layers which may be included within the electronic component 111 may reflect the microwaves and may barely generate heat. In this way, the molding material 130 is selectively heated by the microwave radiation, which improves the heating efficiency and also reduces warpage issues of the substrate 100 and the at least one electronic component 111 mounted thereon. In some other embodiments, the microwave source may be disposed near the loading chamber 120d, which may provide more direct radiation to the molding material 130 and reduce the influence of the microwave radiation process to the substrate 100 and the at least one electronic component 111 mounted thereon.

Furthermore, in this embodiment, the microwave radiation in FIG. 1D may be applied at various frequencies. By sweeping a range of frequencies rapidly, the uniformity of the microwave energy may be increased in comparison with a fixed-frequency microwave radiation. In some embodiments, the microwave radiation is applied at a frequency ranging between 1 GHz and 10 GHz.

In some other embodiments, the piston 120c may include a heater which generates additional heat. The additional heat may raise the ambient temperature of the atmosphere during the microwave radiation process to alleviate heat dissipation from the molding material 130 to the molding chase 120. Also, since the piston 120c is in direct contact with the molding material 130, the additional heat can be convectively transferred to the molding material 130. This may allow for a more rapid temperature raise of the molding material 130 and reduce the microwave energy required to heat the molding material 130 to the certain temperature during this step.

Next, as shown in FIG. 1E, when the microwave radiation is applied to the molding material 130, the piston 120c is moved towards the top cover 120b, for example, manually or automatically by a driver to reduce a volume of the loading chamber 120d. As such, a pressure is applied within the loading chamber 120d where the molding material 130 is disposed. The pressure within the loading chamber 120d can be continuously increased with the movement of the piston 120c. It should be noted that in this embodiment, the microwave radiation and the pressure to the molding material 130 may be applied simultaneously. Under the increased pressured and the high temperature, the molding material 130 in the form of pellets may be melted into a liquid state. Alternatively, in some other embodiments, the microwave radiation and the pressure may be applied sequentially to melt the molding material 130. Then the piston 120c is continuously moved towards the top cover 120b to further increase the pressure within the loading chamber 120d, such that the melted molding material 130 is injected from the loading chamber 120d into the molding cavity 120e through the fluid port 121. Finally, the molding cavity 120e is filled with the molding material 130 injected from the loading chamber 120d, which covers respective surfaces of the at least one electronic component 111 and a front surface of the substrate 100, as illustrated in FIG. 1F. During the process that the molding material 130 is melted and the process that the molding material 130 is injected into and fills the molding cavity 120e, the microwave radiation is continuously applied to the molding material 130. This guarantees that the molding material 130 maintains at a high temperature and keeps in the liquid state before it fully encapsulates the substrate 100 and the at least one electronic component 111.

Next, as shown in FIG. 1F, after the melted molding material 130 fills the molding cavity 120e and encapsulates the substrate 100 and the at least one electronic component 111, a curing process is implemented to the molding material 130 so as to solidify it into a mold cap 140. During the curing process, the microwave radiation is continuously applied to the molding material 130 such that the epoxy-based resin and the curing agent included within the molding material 130 may undergo a chemical reaction to form a crosslinked polymer. In some embodiments, the melted molding material 130 may be heated to a temperature about 140 °C ~ 180 °C, or preferably to a temperature about 150 °C to be solidified into the mold cap 140. Also, the microwave radiation may be applied for a duration between 20 minutes and 2 hours to guarantee a sufficient curing of the molding material 130. In this embodiment, the microwave radiation is applied at variable frequencies during the curing process. In some other embodiments, the curing process may include multiple curing steps which are implemented to the molding material 130 sequentially, and each of the multiple curing steps may have different curing temperatures.

In some other embodiments, the base platform 120a may include a heater which generates additional heat. The additional heat may raise the ambient temperature of the atmosphere during the microwave curing process to alleviate heat dissipation from the molding material 130 to the molding chase 120. Furthermore, the microwave source may be disposed close to the molding cavity 120e and away from the loading chamber 120d, which may provide more direct radiation to the molding material 130 during the curing process. In this way, only a small amount of microwave radiation may reach the molding material 130 within the loading chamber 120d, thereby reducing the microwave energy required from the microwave source and improving the curing efficiency.

In this embodiment, the microwave radiation is continuously applied to heat the molding material 130 during three stages of the whole molding process, that is, a melting stage of the molding material 130 (illustrated in FIG. 1C), an injection stage of the molding material 130 into the molding cavity 120e (illustrated in FIG. 1D) and a curing stage of the molding material 130 (illustrated in FIG. 1E). In this way, all of the heating processes within the aforementioned stages may be implemented using a single microwave radiation apparatus without additional energy sources. In some embodiments, the temperatures to which the molding material 130 may be heated during various stages may be different. To achieve this, the process parameters of the microwave radiation (e.g., power of the microwave source, frequencies of the microwave radiation, heating duration, etc.) in various stages may be tailored individually such that the microwave energy applied to the molding material 130 can be easily adjusted. Therefore, it greatly saves processing costs and simplifies a fabrication procedure. It should be noted that although we separate the whole molding process into three stages for a purpose of illustration, the molding process is carried out by implementing an all-in-one heating process throughout all stages of the whole molding process with the single microwave radiation apparatus.

The continuous microwave radiation process may offer multiple advantages to the formation of the mold cap 140. Firstly, instead of a traditional heating process applied to the whole electronic device, the selective heating of the molding material 130 by microwave radiation may reduce the warpage issues of the substrate 100 and electronic component 111, since the substrate 100 and electronic component 111 are barely heated by the microwave radiation. Secondly, the microwave can penetrate the molding material 130 to supply energy, and thus heat can be generated throughout the molding material 130 in a volumetric manner. This allows for a more uniform heat distribution of the molding material 130, for example, from the surface to the interior of the molding material 130 or across the molding material 130 within the entire molding cavity 120e. Thirdly, after the curing of the molding material 130, higher mobility and diffusion may be achieved throughout the epoxy-based resin network within the formed mold cap 140, which greatly improves the uniformity of the mold cap structure by a more extensive curing process. Thus, a lower curing temperature may be needed to sufficiently cure the molding material 130, thereby reducing energy consumption and improving quality of the formed mold cap 140. Additionally, the microwave induces molecular rotation without destroying molecular bonds due to low energy per photon, which may have little influence on the internal structures of the components of the electronic device. Also, the microwave heating can be started and/or ended quickly, which may reduce the heating duration.

In some embodiments, material(s) of the curing agent as well as the ratio of the resin and the ratio of the curing agent included within the molding material 130 may be appropriately selected. As such, after the chemical reaction of the resin and the curing agent during the curing process, a polymer with a lower crosslink density and longer chains may be produced. For example, the material of the curing agent may include amine-based material(s). The ratio of the resin within the molding material 130 may be between 5% and 10%, and the ratio of the curing agent within the molding material 130 may be between 5% and 7%. The polymer may exhibit a lower storage modulus, which enables the mold cap 140 to possess a softer texture and achieve reduced strain at its interior. Thus, the mold cap 140 may have an improved endurance and an extended service life to protect the encapsulated substrate 100 and the at least one electronic component 111.

In some other embodiments, multiple microwave sources may be arranged around the molding chase 120, more particularly, near the loading chamber 120d and the molding cavity 120e. The microwave sources near the loading chamber 120d and the molding cavity 120e may be operated individually with different parameters during various stages of the whole molding process. For example, when the melting stage of the molding material 130 begins, the microwave source near the loading chamber 120d may be turned on to provide microwave energy to melt the molding material 130 while the microwave source near the molding cavity 120e may be turned off since the molding material 130 has not been injected into the molding cavity 120e. Similarly, when the curing stage of the molding material 130 begins, the microwave source near the molding cavity 120e may be turned on to implement microwave radiation while the microwave source near the loading chamber 120d may be turned off since the molding material 130 within the loading chamber 120d is unnecessary for the formed mold cap 140. This may save energy consumption of the whole molding process and may also allow for higher efficiency of the molding process. In some alternative embodiments, the microwave source may be movable relative to the molding chase 120 to apply microwave radiation to the molding material 130 at different positions during various stages of the molding process.

In some other embodiments, the molding chase 120 may include a coating layer formed on an inner surface of the loading chamber 120d and the molding cavity 120e. The coating layer may include polar material(s) or distributed with polar materials(s), which may include at least one polar material selected from a group of silicon carbide, graphite, charcoal with polarity or carbon with polarity. When the microwave radiation is applied to the molding material 130, the coating layer may also be exposed to the microwave radiation and may also absorb microwave energy. As such, heat may be generated within the coating layer. Since the coating layer is facing towards the molding material 130, the heat generated in the coating layer may be convectively transferred to the molding material 130. This provides additional heat to the molding material 130 during the various stages of the whole molding process. In this way, the molding material 130 may be heated through a hybrid heating mechanism which incorporates the direct microwave heating and the convection heat transferred from the coating layer, which allows for higher energy efficiency of the whole molding process, thus leading to a lower energy demand from the microwave source. Moreover, with a lower microwave energy applied from the microwave source, overall heat generated within the device may be reduced, which may prevent or alleviate a burning effect caused by excessive microwave energy. In short, an excess amount of microwave energy which cannot be absorbed by the molding material 130 may be collected by the coating layer and converted into heat, which, in turn, helps various heating processes of the molding material 130 during the whole molding process.

Next, after the formation of the mold cap 140, the substrate 100 and the at least one electronic component 111 encapsulated by the mold cap 140 can be detached from the molding chase 120. In some embodiments, the top cover 120b may include an eject pin that is inserted at one side of the top cover 120b. When the mold cap 140 is detached from the top cover 120b, the eject pin can protrude from the top cover 120b and be pressed against a peripheral portion of the substrate 100. In this way, the substrate 100 and the at least one electronic component 111 can be pushed away from the top cover 120b, together with the mold cap 140 formed thereon, thereby being demolded from the top cover 120b. In some embodiments, the top cover 120b may include two or more eject pins that are inserted at both sides of the top cover 120b or more locations of the top cover 120b, for sufficiently detaching the mold cap 140 from the top cover 120b. For example, the eject pins may be pressed against the mold cap 140 instead of the substrate 100 itself.

Next, a redundant portion of the solidified molding material 130, for example, the molding material 130 solidified within the loading chamber 120d, may be removed from the mold cap 140 encapsulating the substrate 100 and the electronic component(s) 111. Therefore, an electronic device with reduced warpage issues and lower fabrication costs may be formed.

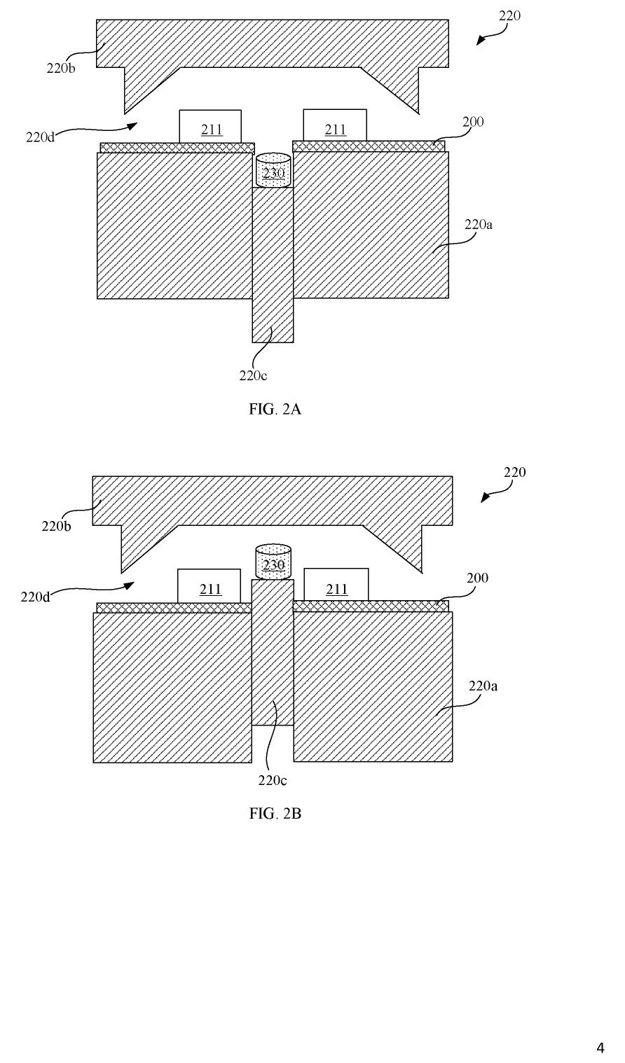

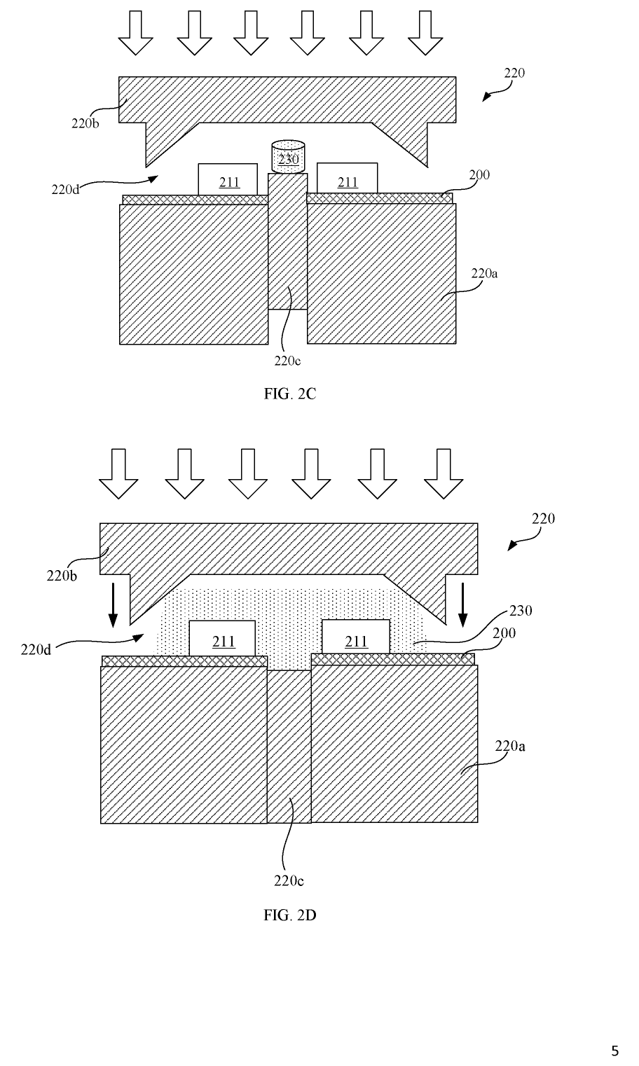

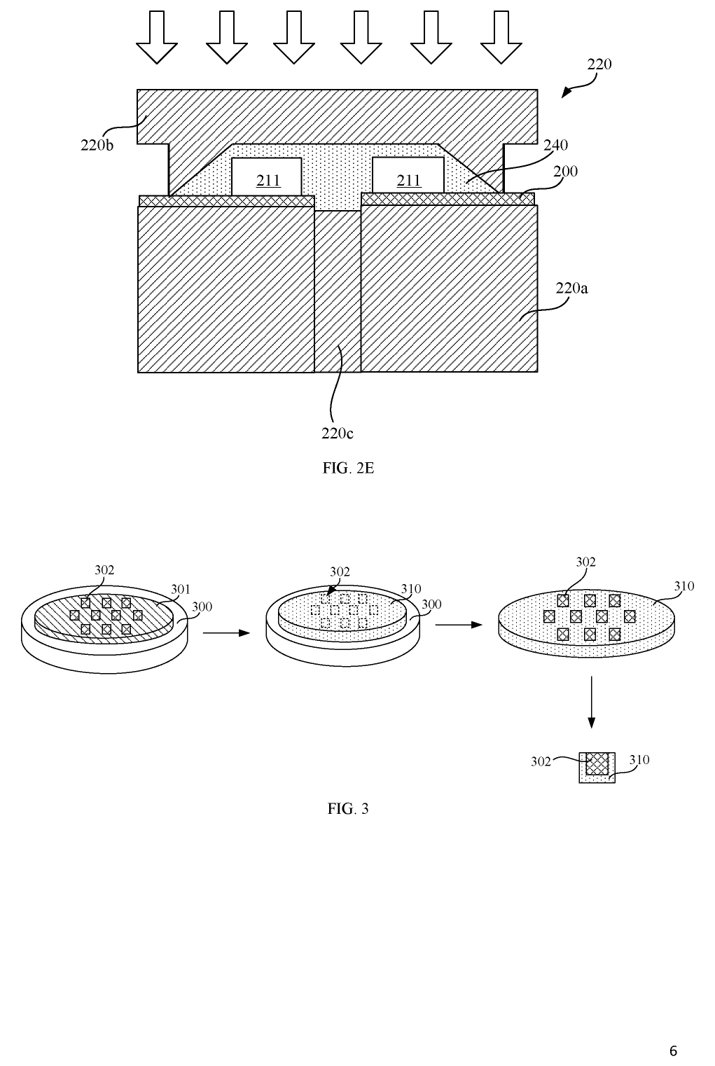

FIGS. 2A to 2E illustrate various steps of a molding process of a method for forming an electronic device according to a second embodiment of the present application. The molding process illustrated in FIGS. 2A to 2E, which is a compression molding process, may be an alternative process to the molding process illustrate in FIGS. 1B to 1F.

As shown in FIG. 2A, a molding chase 220 is provided, which includes a lower chase portion 220a and an upper chase portion 220b which are movable relative to each other and define together the molding cavity 220d. In this embodiment, a substrate 200 with at least one electronic component 211 is disposed onto a front surface of the lower chase portion 220a. Both of the substrate 200 with the at least one electronic component 211 may mostly include non-polar material(s). Furthermore, a piston 220c may be arranged through the lower chase portion 220a and longitudinally movable relative to the lower chase portion 220a. A molding material 230 including a polar material is disposed on a front surface of the piston 220c. In some embodiments, the piston 220c may be arranged within a central part of the lower chase portion 220a. Next, as shown in FIG. 2B, the piston 220c is moved towards the upper chase portion 220b to push the molding material 230 into the molding cavity 220d. Next, a microwave source is placed above a top surface of the molding chase 220. Then microwave radiation is applied from the microwave source and penetrates through the molding chase 220 to reach the molding material 230, as shown in FIG. 2C. Since the molding material 230 includes a polar material, it may absorb microwave energy to generate heat therein. In this way, the molding material 230 may be heated rapidly and sufficiently to a temperature between 150 °C and 190 °C, or preferably, to a temperature between 165 °C and 175 °C, which facilitates its melting process.

Next, as shown in FIG. 2D, when the microwave radiation is applied to the molding material 230, the upper chase portion 220b is moved towards the lower chase portion 220a to reduce a volume of the molding cavity 220d. As such, a pressure is applied within the molding cavity 220d where the molding material 230 is disposed. Under the increased pressure and the high temperature, the molding material 230 may be melted into a liquid state. Then the upper chase portion 220b is continuously moved towards the lower chase portion 220a to further increase the pressure within the molding cavity 220d. Finally, the upper chase portion 220b is attached on the lower chase portion 220a, and the molding cavity 220d is filled with the molding material 230 which covers respective surfaces of the at least one electronic component 211 and a front surface of the substrate 200, as illustrated in FIG. 2E.

During the process that the molding material 230 is melted and the process that the molding material 230 fills the molding cavity 220d, the microwave radiation is continuously applied to the molding material 230. This guarantees that the molding material 230 maintains at a high temperature and keeps in a liquid state before it fully encapsulates the substrate 200 and the at least one electronic component 211. Next, still referring to FIG. 2E, after the melted molding material 230 fills the molding cavity 220d, a curing process is implemented to the molding material 230 through microwave radiation so as to solidify it into a mold cap 240, thereby forming an electronic device. Further details of the molding process may be similar to that illustrated in the molding process illustrated in FIGS. 1B to 1F, which will not be elaborated here.

In this embodiment, since the substrate 200 and electronic component 211 are barely heated by the microwave radiation, the selective heating of the molding material 230 by microwave radiation may reduce the warpage issues of the substrate 200 and electronic component 211. Moreover, the microwave can penetrate the molding material 230 to supply energy, and thus heat can be generated throughout the molding material 230 in a volumetric manner, which allows for a more uniform heat distribution of the molding material 230. Additionally, the microwave radiation is continuously applied to heat the molding material 230 during three stages of the whole molding process, that is, a melting stage of the molding material 230 (illustrated in FIG. 2C), a compression stage of the molding material 230 filling the molding cavity 220d (illustrated in FIG. 2D) and a curing stage of the molding material 230 (illustrated in FIG. 2E). In this way, all of the heating processes of the molding material 230 in the aforementioned stages may be implemented using a single microwave radiation apparatus without additional energy sources, which greatly saves processing costs and simplifies a fabrication procedure.

FIG. 3 illustrates various steps of a method for forming an electronic device according to a third embodiment of the present application.

As shown in FIG. 3, a plurality of electronic components 302 are provided. The electronic components 302 may include various types of electronic modules such as semiconductor chips. The electronic components 302 are mounted onto a carrier substrate 300 via an adhesive layer 301 therebetween. Next, a molding process may be implemented to form a mold cap 310 on the carrier substrate 300 which encapsulates the plurality of electronic components 302. The molding process may be similar to the transfer molding process illustrated in FIGS. 1B to 1F, or the compression molding process illustrated in FIGS. 2A to 2E. Next, the adhesive layer 310 and the carrier substrate 300 are detached from the mold cap 310 and the electronic components 302. Next, solder bumps and/or connection layers may be formed on exposed surfaces of the electronic components 302. Next, the electronic components 302 encapsulated by the mold cap 310 are singulated into a plurality of individual units each including an electronic component 302 encapsulated by a mold cap 310, thereby forming a plurality of electronic devices. Therefore, a mass production can be implemented to produce the electronic devices with reduced warpage issues, lower fabrication costs and simplified fabrication procedures, which is greatly beneficial to semiconductor manufacturing.

While the exemplary method for forming an electronic device of the present application is described in conjunction with corresponding figures, it will be understood by those skilled in the art that modifications and adaptations to the method for forming an electronic device may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic device, the method comprising:
disposing a substrate with at least one electronic component mounted thereon within a molding cavity of a molding chase;
disposing a molding material within the molding chase;
melting the molding material through microwave radiation, and applying a pressure to the molding material to fill the molding cavity with the melted molding material and encapsulate the substrate and the at least one electronic component with the melted molding material; and
curing the molding material through microwave radiation to solidify it into a mold cap.

2. The method of claim 1, wherein the molding chase further comprises a loading chamber for containing the molding material before it is melted and filled into the molding cavity, wherein the loading chamber is fluidly connected with the molding cavity through a fluid port and accommodates therein a piston which moves in response to an external press action.

3. The method of claim 2, wherein disposing a molding material within the molding chase comprises disposing the molding material within the loading chamber; and wherein melting the molding material through microwave radiation and applying a pressure to the molding material comprises:
applying the microwave radiation to the molding material within the loading chamber; and
moving the piston to reduce a volume of the loading chamber when the microwave radiation is applied to the molding material to apply the pressure to melt the molding material and inject the melted molding material from the loading chamber into the molding cavity through the fluid port.

4. The method of claim 1, wherein the molding chase comprises an upper chase portion and a lower chase portion which are movable relative to each other and define together the molding cavity.

5. The method of claim 4, wherein disposing a molding material within the molding chase comprises disposing the molding material within the molding cavity; and wherein melting the molding material through microwave radiation and applying a pressure to the molding material comprises:
applying the microwave radiation to the molding material within the molding cavity; and
moving the upper chase portion towards to the lower chase portion to reduce a volume of the molding cavity when the microwave radiation is applied to the molding material to apply a pressure to melt the molding material, so as to fill the molding cavity with the melted molding material.

6. The method of claim 1, wherein melting the molding material through microwave radiation is performed simultaneously with applying a pressure to the molding material.

7. The method of claim 1, wherein the microwave radiation is continuously applied during the step of melting the molding material and the step of curing the molding material.

8. The method of claim 1, wherein the molding material comprises a polar material.

9. The method of claim 1, wherein melting the molding material through microwave radiation comprises: applying the microwave radiation at variable frequencies.

10. The method of claim 1, wherein curing the molding material through microwave radiation comprises: applying the microwave radiation at variable frequencies.

11. The method of claim 1, wherein curing the molding material through microwave radiation comprises: applying the microwave radiation to heat the molding material to a temperature between 140 °C and 180 °C.

12. The method of claim 1, wherein curing the molding material through microwave radiation comprises: applying the microwave radiation for a duration between 20 minutes and 2 hours.

13. An electronic device which is formed using the method of claim 1.
